(19) United States
(12) Patent Application Publication
(10) Pub. No.: US 2014/0053890 A1
(43) Pub. Date: Feb. 27, 2014

(54) PHOTOVOLTAIC APPARATUS

(71) Applicant: AU OPTRONICS CORPORATION, Hsin-Chu (TW)

(72) Inventor: Chun-Ming YANG, HSIN-CHU (TW)

(73) Assignee: AU Optronics Corporation, Hsin-Chu (TW)

(21) Appl. No.: 13/890,345

(22) Filed: May 9, 2013

(30) Foreign Application Priority Data
Aug. 27, 2012 (CN) 201210308571.2

(51) Int. Cl. H01L 31/048; H01L 31/052

(52) U.S. Cl. CPC H01L 31/0485; H01L 31/052
USPC 136/246; 136/244

(57) ABSTRACT

A photovoltaic apparatus includes N solar cell modules. The solar cell module includes a first sub-loop, a second sub-loop, and at least one junction box. Each of the first sub-loop and second sub-loop has a first end and a second end. The junction box is electrically connected to the first ends and the second ends and connected to another junction box in another adjacent solar cell module. N is a natural number.

### RELATED APPLICATIONS

This application claims priority to China Application Serial Number 201210308571.2, filed Aug. 27, 2012, which is herein incorporated by reference.

### BACKGROUND

1. Technical Field to The present disclosure relates to a photovoltaic apparatus.

2. Description of Related Art

Owing to the shortage of fossil fuels, awareness of the importance of environmental protection is increasing. Therefore, many have been actively developing technologies related to alternative energy and renewable energy in recent years, with the hope that the dependence on fossil fuels and the impact on the environment caused by using fossil energy can be reduced. Among the various kinds of technologies related to alternative energy and renewable energy, the solar cell is a technology that is receiving much attention. The reason for the interest in this technology is that solar cells can directly convert solar energy into electricity, and carbon dioxide or other harmful substances such as nitrogen compounds are not produced during the process of power generation, so that the environment will not be polluted.

Silicon is the most important and widely used material in the semiconductor industry. Today, the technologies behind the production and supply of silicon wafers are already at a quite mature stage. The energy gap of silicon is suitable for absorbing sunlight, and it is for at least this reason that silicon solar cells have become the most widely used solar cells. Generally, a monocrystalline silicon solar cell or a polycrystalline silicon solar cell includes the layers of an external electrode, an anti-reflective layer, an n-type semiconductor layer, and a p-type semiconductor layer.

A common photovoltaic apparatus includes a plurality of solar cell modules and an inverter. Each of the solar cell modules includes a plurality of solar cells that are connected to each other in series, and each of the solar cell modules uses a junction box to electrically connect to another junction box of another solar cell module. In general, the solar cell modules included in the photovoltaic apparatus that are electrically connected to the inverter in series can be arranged in a single row or two rows.

However, when the solar cell modules included in the photovoltaic apparatus are arranged in a single row, the solar cell modules farthest from the inverter must be electrically connected back to the inverter using a long cable, and the long cable needs to be accommodated in an additional hollow pipe. As a result of this configuration, the power loss and material costs of the whole photovoltaic apparatus are increased. In particular, the power of an actuator used in the photovoltaic apparatus must be increased due to the height formed by the solar cell modules that are arranged in two rows.

### SUMMARY

The disclosure provides a photovoltaic apparatus in which each of a plurality of solar cell modules has a plurality of individual sub-loops, so that the solar cell modules that are arranged in a single row can realize a bi-directional circuit connection. In addition, because a single solar cell module has a plurality of individual sub-loops, the photovoltaic apparatus of the disclosure can connect all of the sub-loops and the inverter in series without using cables. Moreover, because junction boxes are disposed substantially at the center of the solar cell modules, all of the sub-loops can be centralized to lead out from the center of the solar cell modules, so that wires of the photovoltaic apparatus can be conveniently received in system frames thereof.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a rear view of a photovoltaic apparatus according to an embodiment of the disclosure;

FIG. 2A is a front view of a solar cell module of the photovoltaic apparatus in FIG. 1;

FIG. 2B is a rear view of a solar cell module of the photovoltaic apparatus in FIG. 1;

FIG. 3 is another rear view of the photovoltaic apparatus in FIG. 1 according to another embodiment of the disclosure;

FIG. 4 is a rear view of a photovoltaic apparatus according to another embodiment of the disclosure;

FIG. 5A is a front view of a solar cell module of the photovoltaic apparatus in FIG. 4; FIG. 5B is a rear view of a solar cell module of the photovoltaic apparatus in FIG. 4;

FIG. 6 is another front view of the solar cell module in FIG. 2A according to another embodiment of the disclosure;

FIG. 7 is a front view of a photovoltaic apparatus according to another embodiment of the disclosure;

FIG. 8 is a front view of a photovoltaic apparatus according to another embodiment of the disclosure;

FIG. 9 is a front view of a photovoltaic apparatus according to another embodiment of the disclosure; and

FIG. 10 is a perspective view of a photovoltaic apparatus according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

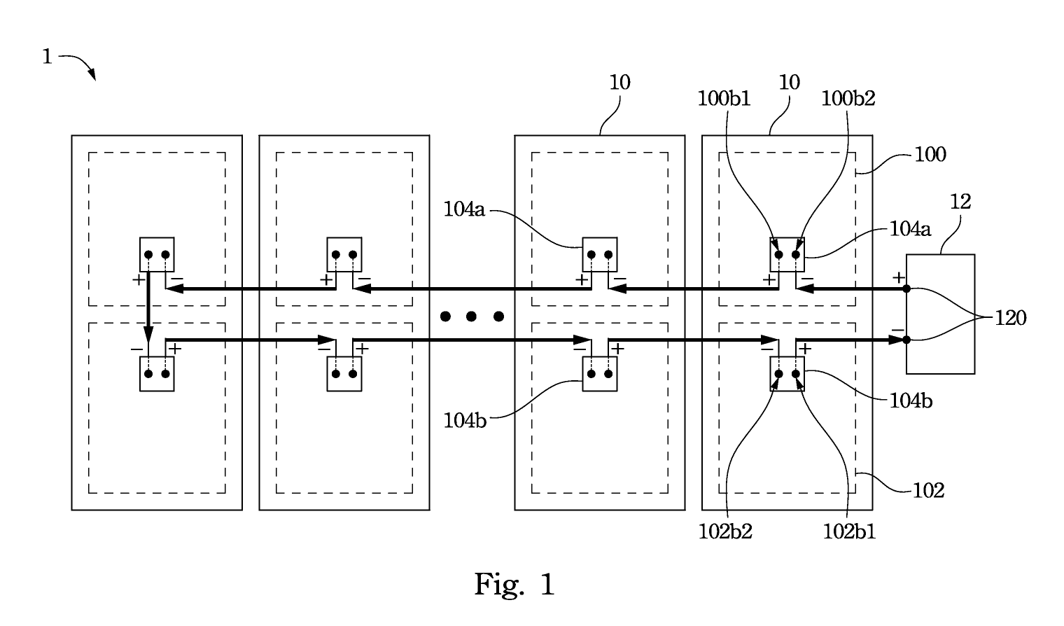

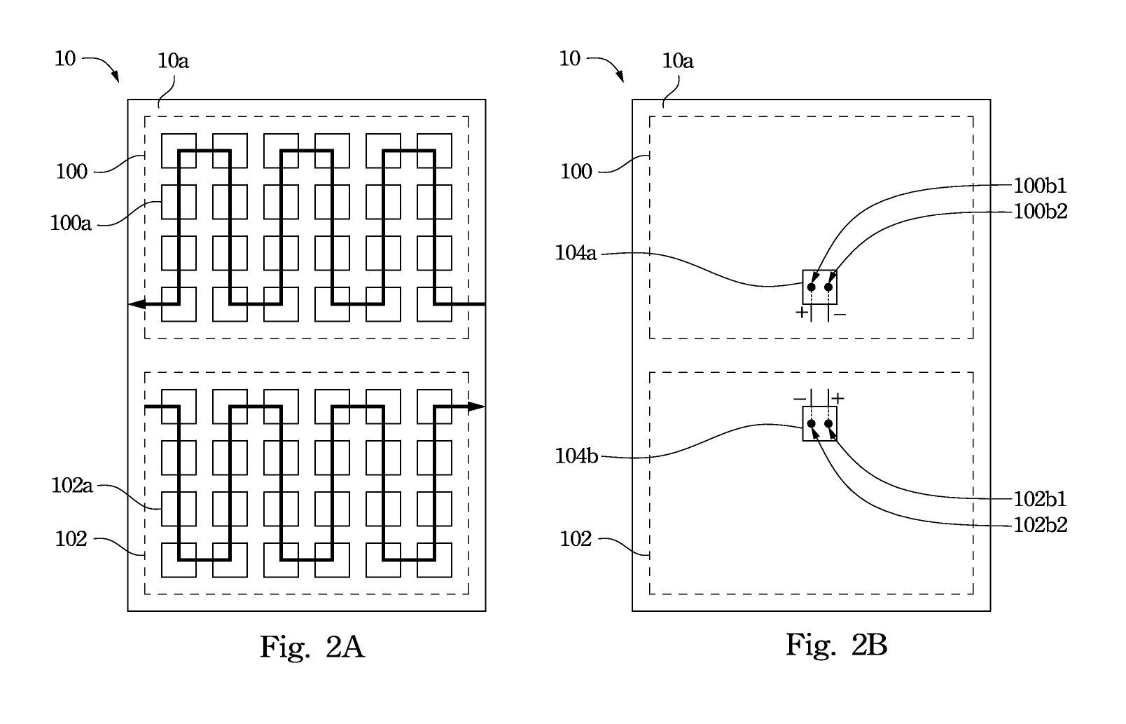

FIG. 1 is a rear view of a photovoltaic apparatus 1 according to an embodiment of the disclosure. FIG. 2A is a front view of a solar cell module of the photovoltaic apparatus 1 in FIG. 1. FIG. 2B is a rear view of a solar cell module of the photovoltaic apparatus 1 in FIG. 1.

As shown in FIG. 1, FIG. 2A, and FIG. 2B, the photovoltaic apparatus 1 includes a plurality of solar cell modules 10. Each of the solar cell modules 10 of the photovoltaic apparatus 1 includes a first sub-loop 100, a second sub-loop 102, and junction boxes 104a, 104b, as shown in FIG. 2B. The first sub-loop 100 has a first end 100b1 and a second end 100b2 of which the polarities are different (e.g., a positive end and a negative end), and the second sub-loop 102 has a first end 102b1 and a second end 102b2 of which the polarities are different. Each of the junction boxes 104a, 104b of the solar cell module 10 also has a first end and a second end of which the polarities are different (not shown). The first end and the second end of the junction box 104a are electrically connected to the first end 100b1 and the second end 100b2 of the first sub-loop 100 respectively and are used to connect to ends of opposite polarities of the junction box 104a of at least one adjacent solar cell module 10.

The first end and the second end of the junction box 104b are electrically connected to the first end 102b1 and the second end 102b2 of the second sub-loop 102 respectively and are used to connect to ends of opposite polarities of the junction box 104b of at least one adjacent solar cell module 10.

In the embodiment of the disclosure, one junction box 104a of the first sub-loop 100 of each of the solar cell modules 10 is connected to the junction box(es) 104a of the first sub-loop 100 of at least one adjacent solar cell module 10, in which opposite polarities of the junction boxes 104a are connected. One junction box 104b of the second sub-loop 102 of each of the solar cell modules 10 is connected to the junction box(es) 104b of the second sub-loop 102 of at least one adjacent solar cell module 10, in which opposite polarities of the junction boxes 104b are connected.

As shown in FIG. 1, each of the solar cell modules 10 is arranged in a row along the same direction. As a result of this configuration, any two adjacent one of the first sub-loops 100 are disposed side by side, any two adjacent one of the second sub-loops 102 are disposed side by side, all of the first sub-loops 100 are electrically connected to each other, and all of the second sub-loops 102 are electrically connected to each other.

The photovoltaic apparatus 1 further includes an inverter 12 which also has first and second ends 120 of opposite polarities. The inverter 12 is configured to transfer direct current to alternating current. The first and second ends 120 of the inverter 12 are electrically connected to the junction box 104a of the first sub-loop 100 and the junction box 104b of the second sub-loop 102 of the first solar cell module 10 that is immediately adjacent to the inverter 12. All of the first sub-loops 100 and the second sub-loops 102 of the photovoltaic apparatus 1 are sequentially connected in series to form a main loop (indicated by the bold arrow lines connected in series in FIG. 1) and connected to the inverter 12.

In order to realize the above configuration, each of the solar cell modules 10 of the photovoltaic apparatus 1 includes the junction box 104a for receiving the first end 100b1 and the second end 100b2 of the first sub-loop 100 thereof, and includes the junction box 104b for receiving the first end 102b1 and the second end 102b2 of the second sub-loop 102 thereof. In addition, the junction boxes 104a, 104b of each of the solar cell modules 10 are located close to where the first sub-loop 100 and the second sub-loop 102 are adjacent to one another. In other words, the junction boxes 104a, 104b of each of the solar cell modules 10 are substantially located at the center of the solar cell module 10.

The first and second ends of the junction box 104a of the first sub-loop 100 of each of the solar cell modules 10 are configured in a manner with the polarities thereof reverse to the polarities of the first and second ends of the junction box 104b of the second sub-loop 102 thereof. For example, the second end of the junction box 104a opposes the first end of the junction box 104b, and the first end of the junction box 104a opposes the second of the junction box 104b, as shown in FIG. 2B.

Furthermore, the first sub-loops 100 of all the solar cell modules 10 are connected in series, the second sub-loops 102 of all the solar cell modules 10 are connected in series, the inverter 12 of the photovoltaic apparatus 1 and the first sub-loops 100 are connected in series, and the inverter 12 and the second sub-loops 102 are connected in series. Details of the connection structure and relationships of components in the photovoltaic apparatus 1 of the disclosure are explained below.

As shown in FIG. 1, in some embodiments, the photovoltaic apparatus 1 includes a plurality of the solar cell modules 10. The solar cell modules 10 of the photovoltaic apparatus 1 are arranged in a side-by-side manner starting from a location immediately adjacent to the inverter 12 and extending away from the inverter 12. For convenience, the solar cell modules 10 will be numbered in sequence from 1 to n, with 1 denoting the solar cell module 10 that is immediately adjacent to the inverter 12 and n denoting the solar cell module 10 that is farthest from the inverter 12. The first sub-loop 100 of the first solar cell module 10 (i.e., the solar cell module 10 that is closest to the inverter 12 and is directly coupled to the inverter 12) is connected in series between the inverter 12 and the first sub-loop 100 of the second solar cell module 10 (i.e., the solar cell module 10 that is second-closest to the inverter 12). The second sub-loop 102 of the first solar cell module 10 is connected in series between the inverter 12 and the second sub-loop 102 of the second solar cell module 10. Therefore, except for the nth solar cell module 10 that is farthest from the inverter 12, the first sub-loop 100 and the second sub-loop 102 in each of the solar cell modules 10 are not electrically connected to each other. As shown in FIG. 1, the first sub-loop 100 and the second sub-loop 102 of the nth solar cell module 10 are connected in series. Furthermore, except for the first and nth solar cell modules 10 (i.e., the closest and farthest solar cell modules 10 relative to the inverter 12), each of the first sub-loops 100 of the other solar cell modules 10 is connected in series between the first sub-loops 100 of two adjacent solar cell modules 10, and each of the second sub-loops 102 of the other solar cell modules 10 is connected in series between the second sub-loops 102 of two adjacent solar cell modules 10.

As shown in FIG. 1, the solar cell modules 10 of the photovoltaic apparatus 1 are closely arranged to each other, and are arranged substantially in a straight line, but the disclosure is not limited in this regard. The direction of the arrangement of the solar cell modules 10 of the photovoltaic apparatus 1 can be adjusted as needed.

Therefore, the solar cell modules 10 that are arranged in a single row of the photovoltaic apparatus 1 of the disclosure can realize a bi-directional circuit connection. In addition, the first sub-loop 100 and the second sub-loop 102 of each of the solar cell modules 10 are at a center location of the solar cell module 10 and lead out from the center of the solar cell module 10 (because the junction boxes 104a, 104b are disposed substantially at the center of the solar cell module 10). As a result, the wires connected among the solar cell modules 10 and the inverter 12 can be conveniently received in system frames (not shown) thereof.

As shown in FIG. 2A, the first sub-loop 100 of each of the solar cell modules 10 is formed by connecting a plurality of solar cells 100a in series, and the second sub-loop 102 of each of the solar cell modules 10 is also formed by connecting a plurality of solar cells 102a in series (indicated by the bold arrow lines in FIG. 2A), but the disclosure is not limited in this regard. In another embodiment of the disclosure, the first sub-loop 100 of each of the solar cell modules 10 is formed by connecting a plurality of solar cells 100a in parallel, and the second sub-loop 102 of each of the solar cell modules 10 is also formed by connecting a plurality of solar cells 102a in parallel.

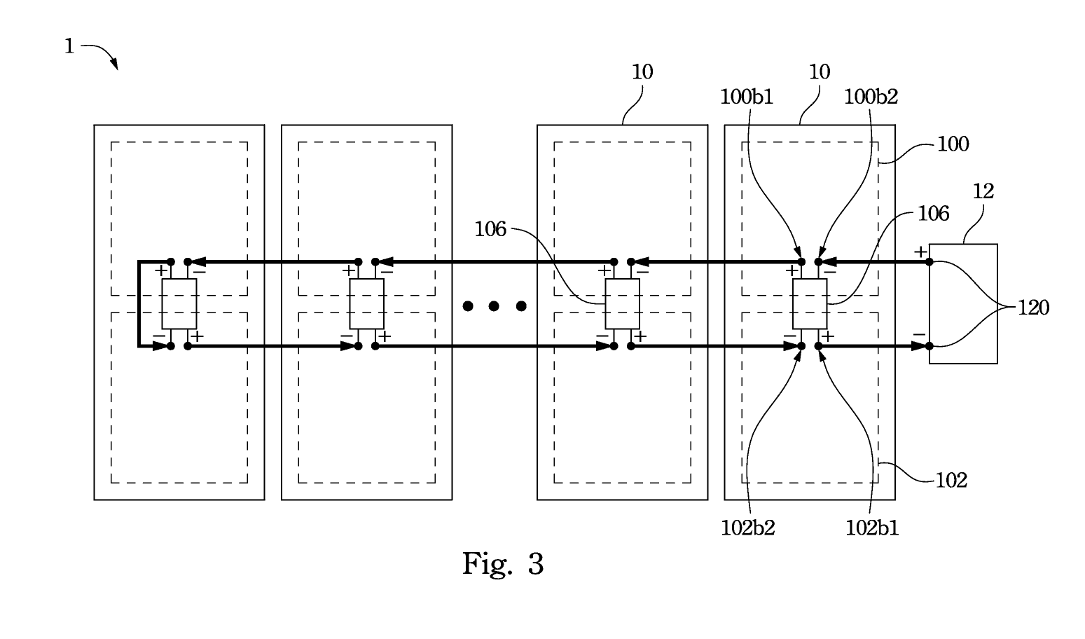

FIG. 3 is another rear view of the photovoltaic apparatus 1 in FIG. 1 according to another embodiment of the disclosure.

As shown in FIG. 3, the solar cell modules 10 included in the photovoltaic apparatus 1 and the first sub-loop 100 and the second sub-loop 102 included in each of the solar cell modules 10 are the same as those of the embodiment in FIG. 1. However, one of the differences between this embodiment and the embodiment in FIG. 1 is that each of the solar cell modules 10 of this embodiment only includes one junction box 106 for use by the first sub-loop 100 and the second sub-loop 102 thereof, but the first sub-loop 100 and the second sub-loop 102 in the solar cell module 10 are not electrically connected to each other. In addition, each of the junction boxes 106 in the embodiment has four outlets. In each of the solar cell modules 10, the first end 100b1 and the second end 100b2 of the first sub-loop 100 and the first end 102b1 and the second end 102b2 of the second sub-loop 102 are electrically connected to the junction box 106, and the junction box 106 is used to respectively connect to ends of opposite polarities of the junction box(es) 106 in at least one adjacent solar cell module 10.

In other words, the first end 100b1 and the second end 100b2 of the first sub-loop 100 of each of the solar cell modules 10 use the junction box 106 to respectively connect to the ends of opposite polarities of the junction box(es) 106 in the at least one adjacent solar cell module 10, so as to electrically connect to the second end 100b2 and the first end 100b1 of the first sub-loop 100 of the at least one adjacent solar cell modules 10. Moreover, the first end 102b1 and the second end 102b2 of the second sub-loop 102 of each of the solar cell modules 10 use the same junction box 106 to respectively connect to the ends of opposite polarities of the junction box 106 in the at least one adjacent solar cell module 10, so as to electrically connect to the second end 102b2 and the first end 102b1 of the second sub-loop 102 of the at least one adjacent solar cell modules 10.

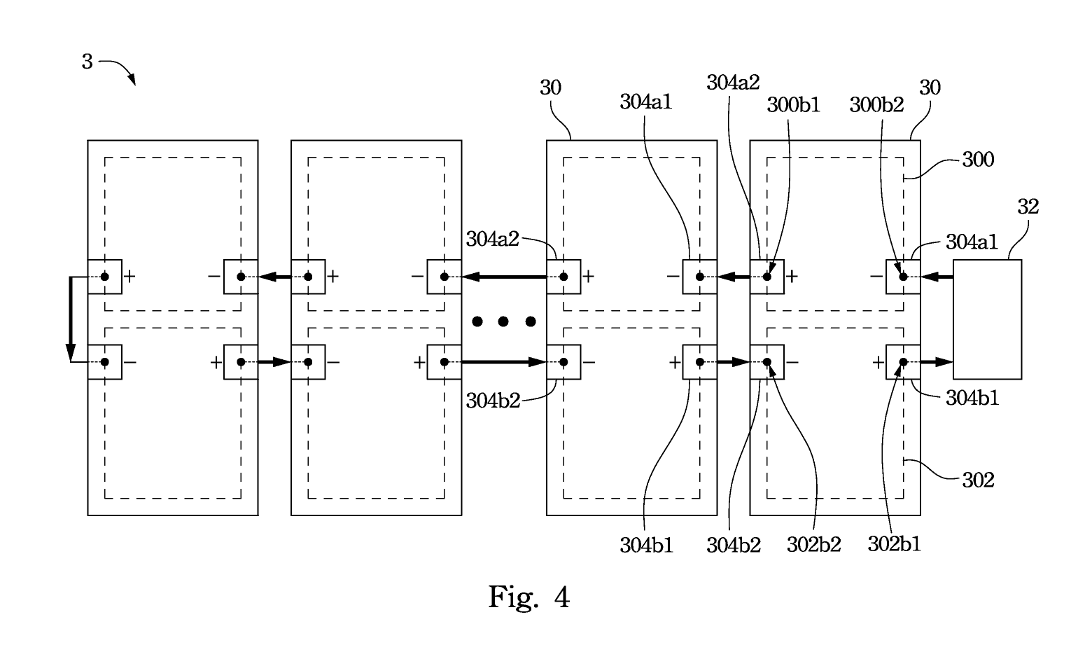

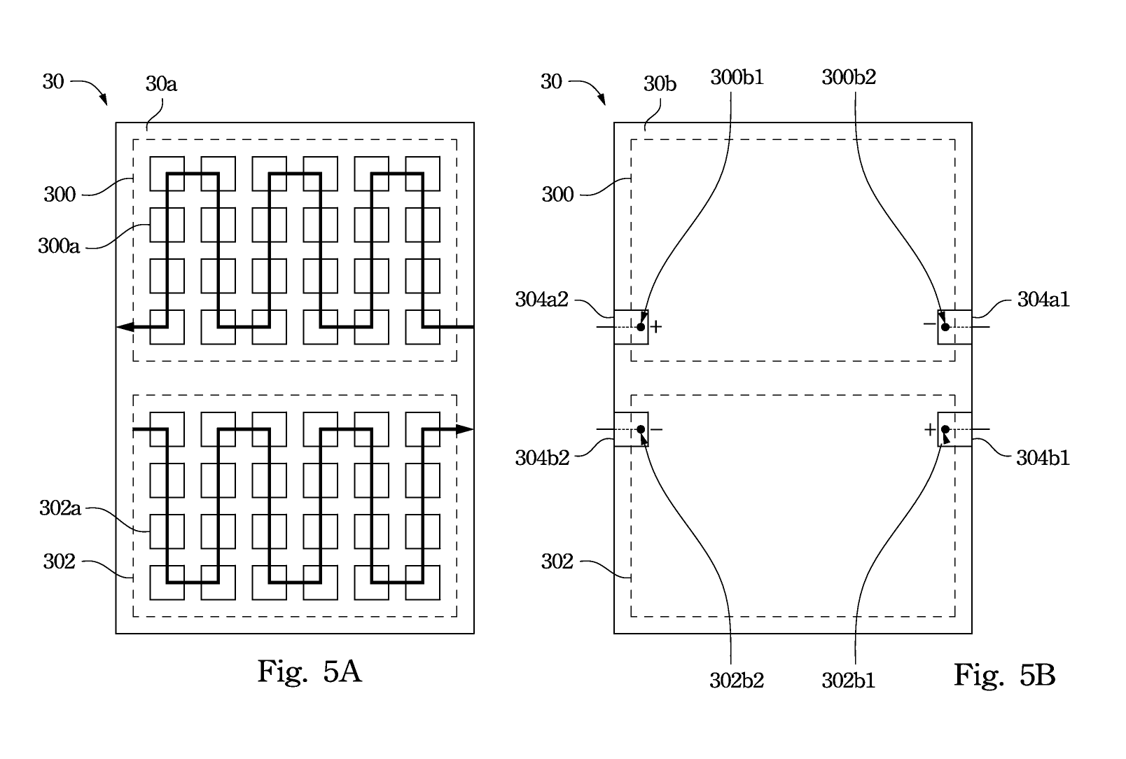

FIG. 4 is a rear view of a photovoltaic apparatus 3 according to another embodiment of the disclosure. FIG. 5A is a front view of a solar cell module of the photovoltaic apparatus 3 in FIG. 4. FIG. 5B is a rear view of a solar cell module the photovoltaic apparatus 3 in FIG. 4.

As shown in FIG. 4, FIG. 5A, and FIG. 5B, the photovoltaic apparatus 3 includes a plurality of solar cell modules 30 and an inverter 32. Each of the solar cell modules 30 of the photovoltaic apparatus 3 includes a first sub-loop 300 and a second sub-loop 302. The first sub-loop 300 of each of the solar cell modules 30 has a first end 300b1 and a second end 300b2, and the second sub-loop 302 of each of the solar cell modules 30 has a first end 302b1 and a second end 302b2. The first sub-loop 300 of each of the solar cell modules 30 is formed by connecting a plurality of solar cells 300a in series, and the second sub-loop 302 of each of the solar cell modules 30 is also formed by connecting a plurality of solar cells 302a in series, as shown in FIG. 5A. The connection structures among the solar cell modules 30 and the inverter 32 can be understood by referring to the explanation of the embodiment in FIG. 1, and therefore, a description in this regard will not be repeated.

One of the differences between the photovoltaic apparatus 3 of this embodiment and the photovoltaic apparatus 1 of the embodiment in FIG. 1 is that the first end 300b1 and the second end 300b2 of the first sub-loop 300 of each of the solar cell modules 30 are respectively located at two opposite sides of the solar cell module 30, and the first end 302b1 and the second end 302b2 of the second sub-loop 302 of each of the solar cell modules 30 are respectively located at two opposite sides of the solar cell module 30.

Additionally, the first end 300b1 and the second end 300b2 of the first sub-loop 300 of each of the solar cell modules 30 are electrically connected to two junction boxes 304a1, 304a2 respectively. With this configuration, the first end 300b1 and the second end 300b2 of the first sub-loop 300 are connected to ends of another first sub-loop(s) 300 of opposite polarities and which are electrically connected to the junction boxes 304a1, 304a2 of at least one adjacent solar cell module 30. Moreover, the first end 302b1 and the second end 302b2 of the second sub-loop 302 of each of the solar cell modules 30 are electrically connected to two junction boxes 304b1, 304b2 respectively. With this configuration, the first end 302b1 and the second end 302b2 of the second sub-loop 302 are connected to ends of another second sub-loop(s) 302 of opposite polarities and which are electrically connected to the junction boxes 304b1, 304b2 of the at least one adjacent solar cell module 30.

It can be seen that the junction boxes 304a1, 304a2 that electrically connect to the first sub-loop 300 in each of the solar cell modules 30 are respectively located at two opposite sides of the solar cell module 30, and the junction boxes 304b1, 304b2 that electrically connect to the second sub-loop 302 in each of the solar cell modules 30 are respectively located at two opposite sides of the solar cell module 30. The junction boxes 304a1, 304a2 of the first sub-loop 300 respectively are a negative end and a positive end, and the junction boxes 304b1, 304b2 of the second sub-loop 302 respectively are a positive end and a negative end. The junction box 304a1 (negative end) and the opposing junction box 304b1 (positive end) are located at the same side of the solar cell module 30, and the junction box 304a2 (positive end) and the opposing junction box 304b2 (negative end) are located at the same side of the solar cell module 30, as shown in FIG. 5B. Through use of such a configuration, therefore, the length of cables used to connect any two adjacent ones of the solar cell modules 30 can be greatly reduced, as shown in FIG. 4.

However, it is no limited in the embodiment. In some practical applications, the junction box 304a1 (negative end) and the opposing junction box 304b1 (positive end) that are located at the same side of the solar cell module 30, and the junction box 304a2 (positive end) and the opposing junction box 304b2 (negative end) that are located at the same side of the solar cell module 30 shown in FIG. 4 and FIG. 5B can be replaced by another single junction box having two ends with different polarities.

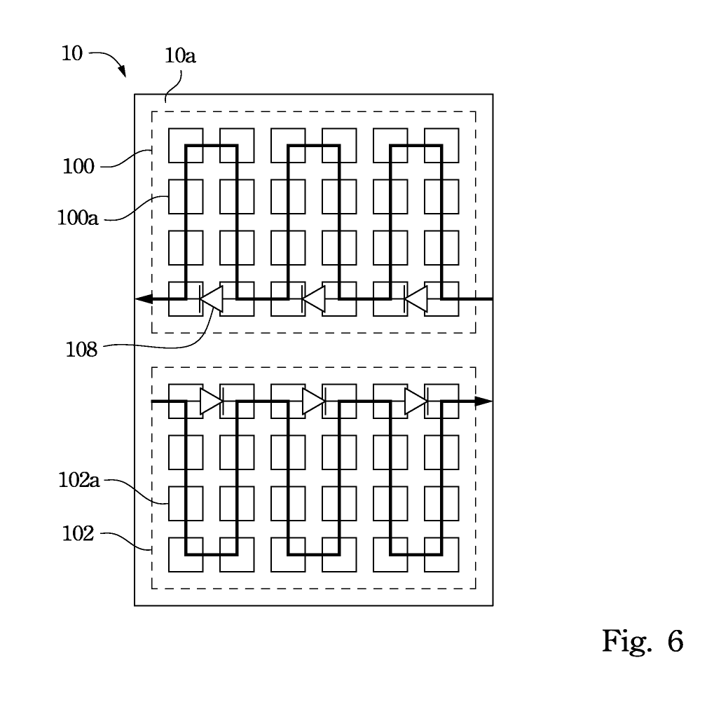

FIG. 6 is another front view of the solar cell module 10 in FIG. 2A according to another embodiment of the disclosure.

As shown in FIG. 6, the solar cells 100a that are connected in series in the first sub-loop 100 and the solar cells 102a that are connected in series in the second sub-loop 102 of the solar cell module 10 are the same as those of the embodiment in FIG. 1. However, one of the differences between this embodiment and the embodiment in FIG. 2A is that the solar cell module 10 of this embodiment further includes a plurality of bypass-diodes 108 in the first sub-loop 100 and the second sub-loop 102. Compared with the conventional solar cell module that only has a single loop, the solar cell module 10 of this embodiment has twice that number (i.e., two sub-loops). As a result, when the same connection structure adopting bypass-diodes (i.e., the connection structure shown in FIG. 6) is used, the number of the bypass-diodes 108 adopted in the solar cell module 10 of the disclosure is twice the number of the bypass-diodes adopted in the conventional solar cell module. Therefore, the solar cell module 10 can enhance the effect of anti-shading, and moreover, loss cause by the hot-spot effect can be effectively reduced.

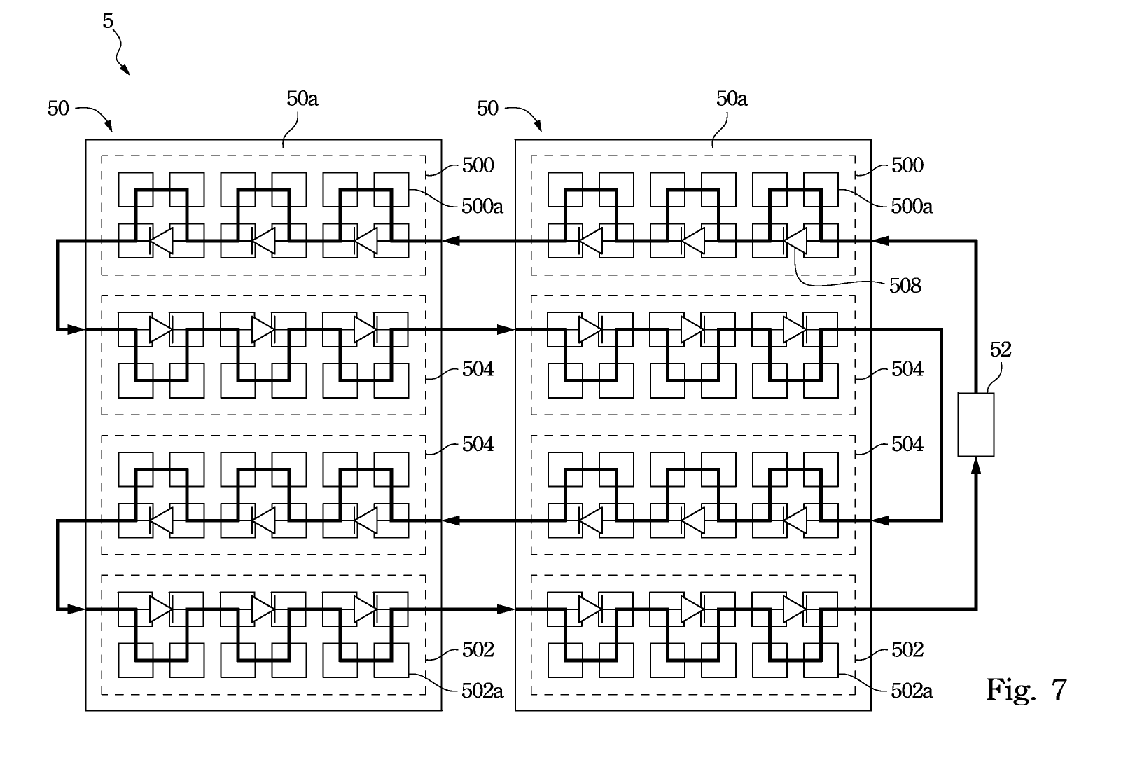

FIG. 7 is a front view of a photovoltaic apparatus 5 according to another embodiment of the disclosure.

As shown in FIG. 7, the photovoltaic apparatus 5 includes at least one solar cell module 50 and an inverter 52. Compared with the embodiment of FIG. 5A, each of the solar cell modules 50 of the photovoltaic apparatus 5 shown in FIG. 7 includes a plurality of different sub-loops (e.g., a first sub-loop 500, a second sub-loop 502, and at least one third sub-loop 504). The third sub-loop 504 of each of the solar cell modules 50 also includes a first end and a second end, which are not shown but can be understood by referring to the related description of the first sub-loop 100 or second sub-loop 102 in FIG. 1.

Moreover, the manner in which the solar cells 500a included in each of the first sub-loops 500 and the solar cells 502a included in each of the second sub-loops 502 are connected can be understood by referring to FIG. 6 and the related description.

The different sub-loops of each of the solar cell modules 50 is connected in series to the different sub-loops of at least one adjacent solar cell module 50 respectively. In detail, the first sub-loops 500 of all the solar cell modules 50 are connected in series, the second sub-loops 502 of all the solar cell modules 50 are connected in series, the third sub-loops 504 of all the solar cell modules 50 are connected in series, and the inverter 52 of the photovoltaic apparatus 5 is respectively connected in series with the first sub-loops 500 and the second sub-loops 502, so as to form a main loop.

It should be pointed out that compared with the conventional solar cell module that only has a single loop, the solar cell module 50 of this embodiment has three or more times that number. As a result, when the same connection structure adopting bypass-diodes (i.e., the connection structure shown in FIG. 7) is used, the number of bypass-diodes 508 adopted in the solar cell module 50 of the disclosure is four times the number of the bypass-diodes adopted in the conventional solar cell module. Theoretically, the effect of anti-shading of the solar cell module 50 of the embodiment is enhanced by a level that is four times that achieved with the conventional solar cell module.

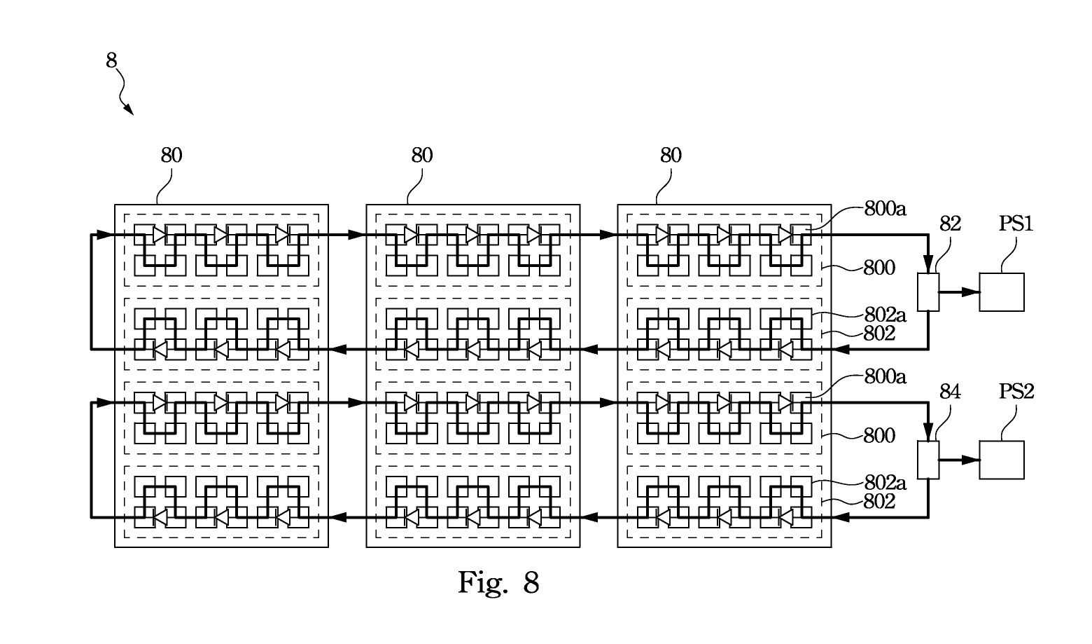

FIG. 8 is a front view of a photovoltaic apparatus 8 according to another embodiment of the disclosure.

As shown in FIG. 8, the photovoltaic apparatus 8 includes a plurality of solar cell module 80 and two inverters 82, 84. Each of the solar cell modules 80 of the photovoltaic apparatus 8 includes two first sub-loops 800 and two second sub-loops 802, but the disclosure is not limited in this regard. The manner in which the solar cells 800a included in each of the first sub-loops 800 and the solar cells 802a included in each of the second sub-loops 802 are connected can be understood by referring to FIG. 6 and the related description.

The inverters 82, 84 are electrically connected to two power systems PS1, PS2, respectively. Each of the inverters 82, 84 is electrically connected to all of the solar cell modules 80, and each of the solar cell modules 80 supplies power to the power systems PS1, PS2 through the inverters 82, 84, respectively.

In detail, one of the first sub-loops 800 and one of the second sub-loops 802 of each of the solar cell modules 80 supply power to the power system PS1 through the corresponding inverter 82, and another of the first sub-loops 800 and another of the second sub-loops 802 of each of the solar cell modules 80 supply power to the power system PS2 through the corresponding inverter 84.

In an embodiment of the disclosure, the power system PS1 is a stand-alone power system, and the power system PS2 is a grid-parity power system. In another embodiment of the disclosure, both of the power systems PS1, PS2 are individual stand-alone power systems or grid-parity power systems.

Therefore, the photovoltaic apparatus 8 of the disclosure can supply power to the different power systems PS1, PS2 respectively through the inverters 82, 84 at the same time under the configuration that the solar cell modules 80 are arranged in a single row.

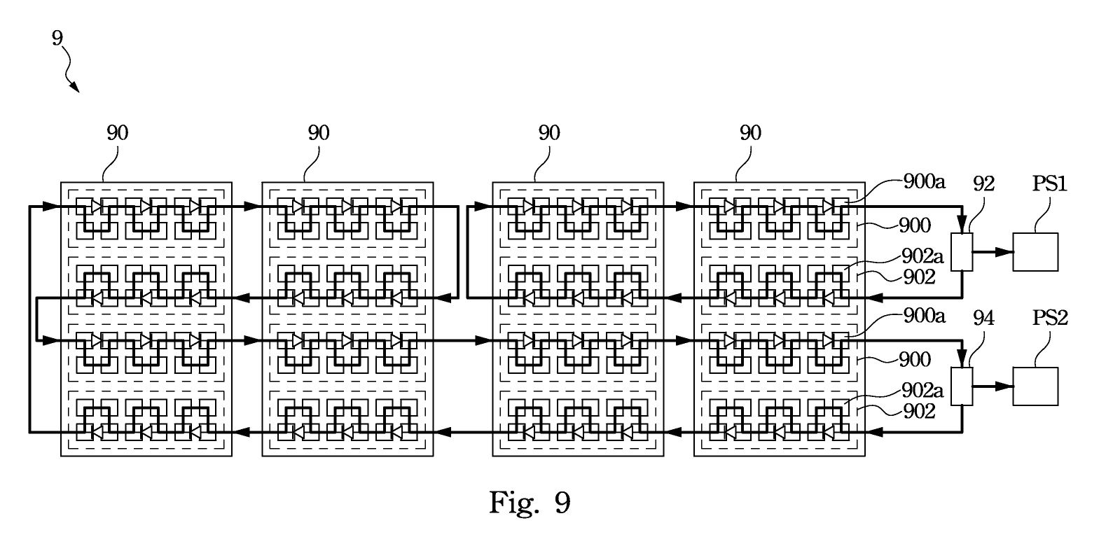

FIG. 9 is a front view of a photovoltaic apparatus 9 according to another embodiment of the disclosure.

As shown in FIG. 9, the photovoltaic apparatus 9 includes a plurality of solar cell module 90 and two inverters 92, 94. Each of the solar cell modules 90 of the photovoltaic apparatus 9 includes two first sub-loops 900 and two second sub-loops 902, but the disclosure is no limited in this regard. The manner in which the solar cells 900a included in each of the first sub-loops 900 and the solar cells 902a included in each of the second sub-loops 902 are connected can be understood by referring to FIG. 6 and the related description.

The inverters 92, 94 are electrically connected to two power systems PS1, PS2, respectively. Each of the inverters 92, 94 is electrically connected to at least one of the solar cell modules 90, and each of the solar cell modules 90 supplies power to at least one of the power systems PS1, PS2 respectively through the inverters 92, 94. In the embodiment of the disclosure, two of the solar cell modules 90 that are close to the inverters 92, 94 supply power to the power systems PS1 through the inverters 92, and all of the four solar cell modules 90 supply power to the power systems PS2 through the inverters 94, but the disclosure is not limited in this regard.

In detail, one of the first sub-loops 900 and one of the second sub-loops 902 of each of the two solar cell modules 90 that are close to the inverters 92, 94 supply power to the power system PS1 through the corresponding inverter 92, and another of the first sub-loops 900 and another of the second sub-loops 902 of each of the two solar cell modules 90 that are close to the inverters 92, 94 supply power to the power system PS2 through the corresponding inverter 94. Moreover, all of the first sub-loops 900 and all of the second sub-loops 902 of the two solar cell modules 90 that are away from the inverters 92, 94 are electrically connected to one of the first sub-loop 900 and one of second sub-loops 902 of each of the two solar cell modules 90 that are close to the inverters 92, 94, so as to supply power to the power system PS2 through the corresponding inverter 94.

Therefore, it can be seen that the electrical connections among the first sub-loops 900 and the second sub-loops 902 of the solar cell modules 90 can be adjusted according to different electricity demands of the different power systems PS1, PS2.

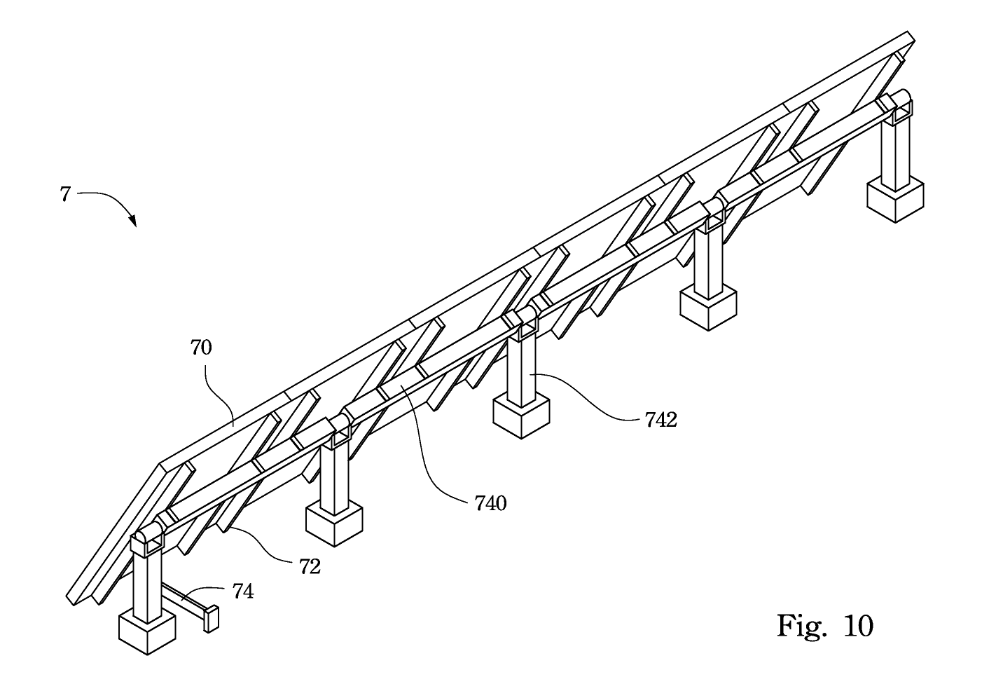

FIG. 10 is a perspective view of a photovoltaic apparatus 7 according to another embodiment of the disclosure.

As shown in FIG. 10, the photovoltaic apparatus 7 includes a plurality of solar cell modules 70, a plurality of frames 72, and an actuator 74. The detailed structure of each of the solar cell modules 70 and the connection structures and relationships among the solar cell modules 70 and the inverter (not shown) can be understood by referring to the description of the embodiments in FIG. 1 and FIG. 4, and so a description in this regard will not repeated.

The photovoltaic apparatus 7 of the embodiment is able to adjust the angle of the solar cell modules 70 according to the sunshine (i.e., to face the sun). The solar cell modules 70 are fixed on the frames 72. In detail, each of the solar cell modules 70 is fixed on two corresponding ones of the frames 72. The actuator 74 has a hollow pipe 740 and supporting legs 742. The hollow pipe 740 is pivotally connected to the supporting legs 742. The frames 72 are fixed to the hollow pipe 740 of the actuator 74. Therefore, when the actuator 74 of the photovoltaic apparatus 7 actuates the hollow pipe 740 to rotate relative the supporting legs 742, the frames 72 are rotated together with the hollow pipe 740. Furthermore, electrical connections among the solar cell modules of the photovoltaic apparatus 7 are made within the hollow pipe 740 of the actuator 74, so cables that are electrically connected among the solar cell modules 70 and the inverter can be centralized and received in the hollow pipe 740 of the actuator 74.

According to the foregoing recitations of the embodiments of the disclosure, the disclosure provides a photovoltaic apparatus in which each of solar cell modules has a plurality of individual sub-loops, so the solar cell modules that are arranged in a single row can realize bi-directional circuit connection. The photovoltaic apparatus assembled by the solar cell modules that are arranged in a single row can reduce the burden on system frames and the power consumed by an actuator. In addition, because a single solar cell module has a plurality of individual sub-loops, the photovoltaic apparatus of the disclosure can connect all of the sub-loops and the inverter in series without using cables. Moreover, because junction boxes are disposed substantially at the center of the solar cell modules, all of the sub-loops can be centralized to lead out from the center of the solar cell modules, so that wires of the photovoltaic apparatus can be conveniently received in the system frames thereof.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photovoltaic apparatus comprising N solar cell modules, wherein each of the solar cell modules comprises:
a first sub-loop having a first end and a second end, wherein the polarity of the first end is different from the polarity of the second end;
a second sub-loop having a first end and a second end; and
at least one junction box electrically connected to the first and second ends of the first sub-loop and the first and second ends of the second sub-loop,
wherein the first sub-loop is electrically connected to another first sub-loop in at least one adjacent solar cell module via the at least one junction box, the second sub-loop is electrically connected to another second sub-loop in the at least one adjacent solar cell module via the at least one junction box, and N is a natural number.

2. The photovoltaic apparatus of claim 1, wherein the at least one junction box is located between the first sub-loop and the second sub-loop of the solar cell module.

3. The photovoltaic apparatus of claim 1, wherein the solar cell module comprises two junction boxes, one of the junction boxes is electrically connected to the first and second ends of the first sub-loop and the other one of junction boxes is electrically connected to the first and second ends of the second sub-loop.

4. The photovoltaic apparatus of claim 1, wherein the solar cell module comprises four junction boxes, and the junction boxes are electrically connected to the first end of the first sub-loop, the second end of the first sub-loop, the first end of the second sub-loop, and the second end of the second sub-loop respectively.

5. The photovoltaic apparatus of claim 4, wherein the junction boxes are located at two opposite sides of the solar cell module, two of the junction boxes that are respectively electrically connected to the first end of the first sub-loop and the second end of the second sub-loop are located at the same side of the solar cell module, and the other two of the junction boxes that are respectively electrically connected to the second end of the first sub-loop and the first end of the second sub-loop are located at the same side of the solar cell module.

6. The photovoltaic apparatus of claim 1, further comprising an inverter electrically connected to a power system and configured to transfer direct current to alternating current, wherein with respect to the N solar cell modules, the inverter is electrically connected to the first end of the first sub-loop and the second end of the second sub-loop of one of the solar cell modules.

7. The photovoltaic apparatus of claim 6, wherein the second end of the first sub-loop of the N-th solar cell module among the N solar cell modules is electrically connected to the first end of the second sub-loop of the N-th solar cell module, the second end of the first sub-loop of each of the other solar cell modules is electrically coupled to the first end of the first sub-loop of another adjacent solar cell module, and the first end of the second sub-loop of each of the other solar cell modules is electrically coupled to the second end of the second sub-loop of another adjacent solar cell module.

8. The photovoltaic apparatus of claim 6, wherein each of the solar cell modules further comprises at least one third sub-loop, and the at least one third sub-loop has another first end and another second end.

9. The photovoltaic apparatus of claim 8, wherein the second end of the first sub-loop of each of the solar cell modules is electrically coupled to the first ends of the first sub-loops of the adjacent solar cell modules, the second end of the second sub-loop of each of the solar cell modules is electrically coupled to the first ends of the second sub-loops of the adjacent solar cell modules, and the second end of the third sub-loop of each of the solar cell modules is electrically coupled to the first ends of the third sub-loops of the adjacent solar cell modules.

10. The photovoltaic apparatus of claim 8, wherein the second ends of the first sub-loops of the other solar cell modules are electrically connected to the first ends of the third sub-loops of the other solar cell modules, and the second ends of the third sub-loops of the other solar cell modules are electrically connected to the first ends of the second sub-loops of the other solar cell modules, so as to form a main loop.

11. The photovoltaic apparatus of claim 10, wherein each of the first sub-loops, the second sub-loops, and the third sub-loops comprises a plurality of bypass-diodes coupled between any two solar cells.

12. The photovoltaic apparatus of claim 1, wherein each of the first sub-loop and the second sub-loop is formed by connecting a plurality of solar cells in series or in parallel.

13. The photovoltaic apparatus of claim 1, further comprising:
a plurality of frames, wherein the solar cell modules are fixed on the frames; and
an actuator having a hollow pipe for receiving a plurality of cables that electrically connect the solar cell modules, the actuator actuating the frames to rotate.

14. The photovoltaic apparatus of claim 1, further comprising a plurality of inverters electrically connected to a plurality of power systems, respectively, each of the inverters is electrically connected to at least one of the solar cell modules, each of the solar cell modules supplies power to at least one of the power systems through the corresponding inverter.

15. The photovoltaic apparatus of claim 14, wherein each of the solar cell modules comprises a plurality of first sub-loops and a plurality of second sub-loops, at least one of the first sub-loops and at least one of the second sub-loops of each of the solar cell modules supply power to one of the power systems through the corresponding inverter.

16. A solar tracking photovoltaic systems comprising:
a plurality of solar cell modules according to claim 1, the solar cell modules being electrically connected in series and arranged in a straight line; and
a plurality of frames, wherein the solar cell modules are fixed on the frames.

17. The solar tracking photovoltaic system of claim 16, wherein the frames are perpendicular to the straight line, and each of the solar cell modules is fixed on two corresponding ones of the frames.

18. The solar tracking photovoltaic system of claim 16, further comprising an actuator, the actuator having a hollow pipe for receiving a plurality of cables that electrically connect the solar cell modules, the actuator actuating the frames to rotate.

19. The solar tracking photovoltaic system of claim 18, wherein the actuator further comprises a plurality of supporting legs, the hollow pipe is pivotally connected to the supporting legs along the straight line, the frames are fixed to the hollow pipe, and the actuator actuates the hollow pipe to rotate relative the supporting legs, so as to make the frames rotate together with the hollow pipe.
